(19) United States
(12) Patent Application Publication
(10) Pub. No.: US 2024/0074331 A1
(43) Pub. Date: Feb. 29, 2024

(54) METHOD AND APARATUS FOR MEASURING NON-LOCAL CONDUCTANCE

(71) Applicant: Microsoft Technology Licensing, LLC, Redmond, WA (US)

(72) Inventors: Esteban Adrian MARTINEZ, Copenhagen (DK); Saulius VAITIEKENAS, Copenhagen (DK); Lucas CASPARIS, Copenhagen (DK); Esben Bork HANSEN, Copenhagen (DK)

(73) Assignee: Microsoft Technology Licensing, LLC, Redmond, WA (US)

(21) Appl. No.: 18/261,102

(22) PCT Filed: Jan. 13, 2021
(86) PCT No.: PCT/EP2021/050587

§ 371 Date: Jul. 11, 2023

(51) Int. Cl. H10N 60/10; G01R 19/00; H10N 60/01

(52) U.S. Cl. CPC H10N 60/128; G01R 19/0092; H10N 60/01

(57) ABSTRACT

A semiconductor-superconductor hybrid device comprises a semiconductor component having first and second terminals, first and second gate electrodes for electrostatically gating the first and second terminals. A second gate electrode electrostatically gates the second terminal, and a superconductor component is configured for energy level hybridisation with the semiconductor component. A method of measuring a non-local conductance of the semiconductor component comprises applying a first gate voltage to the first gate electrode to gate the first terminal to an open regime, applying a second gate voltage to the second gate electrode to gate the second terminal to a tunnelling regime, applying a bias voltage to the first terminal, and while applying the first gate voltage, the second gate voltage, and the bias voltage, measuring a current through the second terminal; with the superconductor component grounded.

### BACKGROUND

Topological quantum computing is based on the phenomenon whereby non-abelian anyons, in the form of Majorana zero modes (MZMs), can be formed in regions where a semiconductor is coupled to, i.e. capable of undergoing energy level hybridisation with, a superconductor. A non-abelian anyon is a type of quasiparticle, meaning not a particle per se, but an excitation in an electron liquid that behaves at least partially like a particle. An MZM is a particular bound state of such quasiparticles.

Under certain conditions, MZMs can be formed in a nanowire formed from a length of semiconductor coated with a superconductor, close to the semiconductor-superconductor interface. When MZMs are induced in the nanowire, it is said to be in the “topological regime”. To induce this requires a magnetic field, conventionally applied externally, and also cooling of the nanowire to a temperature that induces superconducting behaviour in the superconductor material. It may also involve gating a part of the nanowire with an electrostatic potential.

By forming a network of such nanowires and inducing the topological regime in parts of the network, it is possible to create a quantum bit (qubit) which can be manipulated for the purpose of quantum computing. A quantum bit, or qubit, is an element upon which a measurement with two possible outcomes can be performed, but which at any given time (when not being measured) can in fact be in a quantum superposition of the two states corresponding to the different outcomes.

To induce an MZM, the device is cooled to a temperature where the superconductor (e.g. Aluminium, Al) exhibits superconducting behaviour. The superconductor causes a proximity effect in the adjacent semiconductor, whereby a region of the semiconductor near the interface with the superconductor also exhibits superconducting properties. I.e. a topological phase behaviour is induced in the adjacent semiconductor as well as the superconductor. It is in this region of the semiconductor where the MZMs are formed.

Another condition for inducing the topological phase where MZMs can form is the application of a magnetic field in order to lift the spin degeneracy in the semiconductor. Degeneracy in the context of a quantum system refers to the case where different quantum states have the same energy level. Lifting the degeneracy means causing such states to adopt different energy levels. Spin degeneracy refers to the case where different spin states have the same energy level. Spin degeneracy can be lifted by means of a magnetic field, causing an energy level spilt between the differently spin-polarized electrons. This is known as the Zeeman effect. Typically, the magnetic field is applied by an external electromagnet. However, U.S. Ser. No. 16/246,287 has also disclosed a heterostructure in which a layer of a ferromagnetic insulator is disposed between the superconductor and semiconductor in order to internally apply the magnetic field for lifting the spin degeneracy, without the need for an external magnet. Examples given for the ferromagnetic insulator included compounds of heavy elements in the form of EuS, GdN, Y₃Fe₅O₁₂, Bi₃Fe₅O₁₂, YFeO₃, Fe₂O₃, Fe₃O₄, GdN, Sr₂CrReO₆, CrBr₃/CrI₃, YTiO₃ (the heavy elements being Europium, Gadolinium, Yttrium, Iron, Strontium and Rhenium).

Inducing MZMs typically also requires gating the nanowire with an electrostatic potential. The electrostatic potential is applied using a gate electrode. Applying an electrostatic potential manipulates the number of charge carriers in the conductance band or valence band of the semiconductor component.

As illustrated in FIG. 1, in order to create good quality devices in which the MZMs are long-lived, it is preferable to have a large topological gap E_{g}. A material in the topological phase (whether a superconductor or a region of proximity-induced superconductivity in a semiconductor) exhibits distinct energy bands: a lower band 101 and an upper band 102. The lower band 101 is a band where the quasiparticle energy E falls in a lower range, and the upper band (or “excitation band”) 102 is a band of higher quasiparticle energy. The topological gap E_{g} is an energy window between the upper and lower bands 101, 102 where no quasiparticles can exist due to the quantized (discrete) nature of the quasiparticle energy levels. The lower band 101, upper band 102 and topological gap E_{g} are analogous to the valence band, conduction band and band gap for electrons in a semiconductor. In the upper, excitation, band 102 the quasiparticles can propagate freely through the superconductor (or proximity-induced region in a semiconductor), analogous to the electrons in the valence band in a semiconductor.

The Majoranas, whose states form the MZMs, form the lower band 101. The Majoranas are part of the computational space, i.e. the properties of the system being exploited for the quantum computing application in question. In other words, the MZMs are the operating elements of the qubit. On the other hand, the particle-like excitations (quasiparticles) in the upper band 102 are not part of the computational space. If these quasiparticles cross the topological energy gap E_{g} into the lower band 101, for example due to thermal fluctuations, then this will destroy at least some of the MZMs. This is sometimes referred to as “poisoning” the MZMs. The gap E_{g} provides protection for the MZMs against such poisoning. The probability of a quasiparticle existing in the upper band and crossing the gap E_{g} from the upper to the lower band is proportional to e^{-E}^{_{g}}^{/kT} where T is temperature and k is the Boltzmann constant. Hence the larger the topological gap, the more protection is afforded to the MZMs against poisoning from the harmful quasiparticles in the upper band 102.

A more detailed treatment of the theory of operation of hybrid semiconductor-superconductor devices is provided by Stanescu et al (Physical Review B 84, 144522 (2011)) and Winkler et al (Physical Review B 99, 245408 (2019)).

It would be desirable to allow for the measurement of the properties of semiconductor-superconductor hybrid devices, and in particular to allow for measurement of the size of the topological gap. It would also be desirable to allow for the selection of appropriate operating parameters for semiconductor-superconductor hybrid devices.

### SUMMARY

In one aspect, there is provided a method for measuring a non-local conductance of a semiconductor component of a semiconductor-superconductor hybrid device. The semiconductor-superconductor hybrid device comprises: the semiconductor component, the semiconductor component having a first terminal and a second terminal; a first gate electrode for electrostatically gating the first terminal; a second gate electrode for electrostatically gating the second terminal; and a superconductor component configured to be capable of energy level hybridisation with the semiconductor component. The method comprises: applying a first gate voltage to the first gate electrode to gate the first terminal to an open regime; applying a second gate voltage to the second gate electrode to gate the second terminal to a tunnelling regime; applying a bias voltage to the first terminal; and while applying the first gate voltage, the second gate voltage, and the bias voltage, measuring a current through the second terminal. During the measurement, the superconductor component is grounded.

In another aspect, there is provided an apparatus for measuring a non-local conductance of a semiconductor component of a semiconductor-superconductor hybrid device, the semiconductor-superconductor hybrid device having a semiconductor component and a superconductor component, the superconductor component being configured to be capable of energy level hybridisation with the semiconductor component. The apparatus comprises: a processing unit; a data storage; and connection circuitry operably connectable to the semiconductor-superconductor hybrid device; wherein the data storage stores code which, when executed by the processing unit, causes the apparatus to perform operations comprising: applying a first gate voltage to a first gate electrode to gate a first terminal of the semiconductor component to an open regime; applying a second gate voltage to a second gate electrode to gate a second terminal of the semiconductor component to a tunnelling regime; applying a bias voltage to the first terminal; and while applying the first gate voltage, the second gate voltage, and the bias voltage, measuring a current through the second terminal.

A still further aspect provides a computer-readable medium storing code which, when executed by a processing unit of an apparatus having connection circuitry operably connectable to the semiconductor-superconductor hybrid device, causes the apparatus to perform operations comprising: applying a first gate voltage to a first gate electrode to gate a first terminal of the semiconductor component to an open regime; applying a second gate voltage to a second gate electrode to gate a second terminal of the semiconductor component to a tunnelling regime; applying a bias voltage to the first terminal; and while applying the first gate voltage, the second gate voltage, and the bias voltage, measuring a current through the second terminal.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1 is a diagram illustrating the concept of a topological gap;

FIG. 2A is schematic cross section of an illustrative semiconductor-superconductor hybrid device;

FIG. 2B is a scanning electron microscopy, SEM, micrograph of a device of the type shown in FIG. 2A;

FIG. 3 is a block diagram of an apparatus for measuring a non-local conductance of a semiconductor component of a semiconductor-superconductor hybrid device;

FIG. 4 is a flowchart outlining a method for measuring a non-local conductance of a semiconductor-superconductor hybrid device;

FIG. 5 is a plot showing results discussed in Example 1.

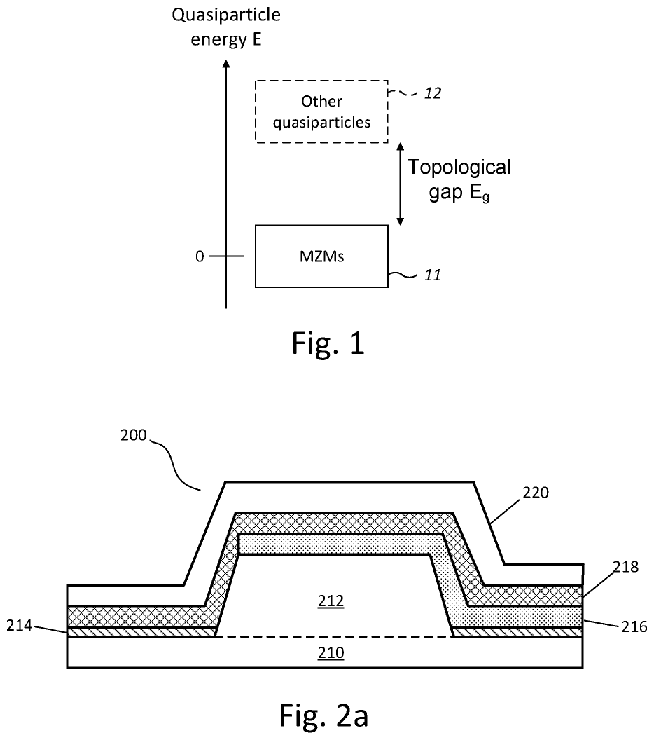

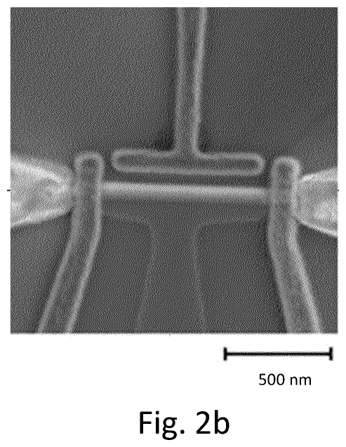

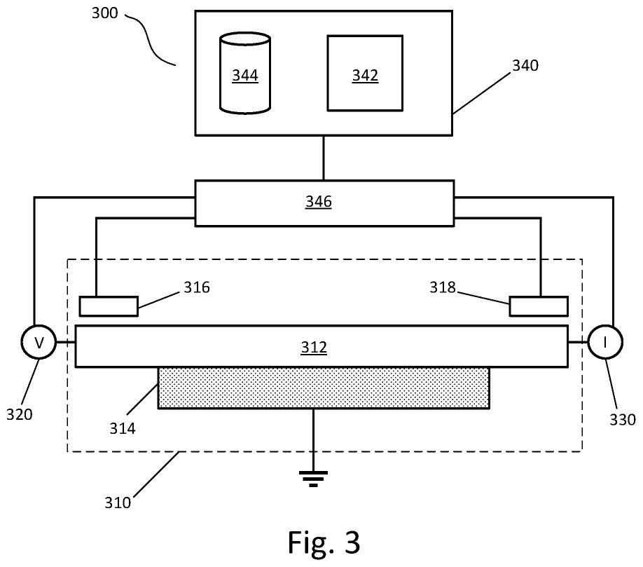

FIGS. 2A and 3 are not to scale. In FIG. 3, the relative size of the semiconductor-superconductor hybrid device is exaggerated for ease of representation.

### DETAILED DESCRIPTION

The verb ‘to comprise’ is used herein as shorthand for ‘to include or to consist of’. In otherwords, although the verb ‘to comprise’ is intended to be an open term, the replacement of this term with the closed term ‘to consist of’ is explicitly contemplated, particularly where used in connection with chemical compositions.

Directional terms such as “top”, “bottom”, “left”, “right”, “above”, “below”, “horizontal” and “vertical” are used herein for convenience of description and relate to the orientation shown in the drawings. For the avoidance of any doubt, this terminology is not intended to limit orientation in an external frame of reference.

As used herein, the term “superconductor” refers to a material which becomes superconductive when cooled to a temperature below a critical temperature, T_{c}, of the material. The use of this term is not intended to limit the temperature of the device.

A “nanowire” is an elongate member having a nano-scale width, and a length-to-width ratio of at least 100, or at least 500, or at least 1000. A typical example of a nanowire has a width in the range 10 to 500 nm, optionally 50 to 100 nm or 75 to 125 nm. Lengths are typically of the order of micrometres, e.g. at least 1 μm, or at least 10 μm.

The term “coupling” in the context of the present disclosure refers to the hybridisation of energy levels.

A “semiconductor-superconductor hybrid structure”, also referred to herein as a “hybrid device”, comprises a semiconductor component and a superconductor component which may become coupled to one another under certain operating conditions. In particular, this term refers to a structure capable of showing topological behaviour such as Majorana zero modes, or other excitations useful for quantum computing applications. The operating conditions generally comprise cooling the structure to a temperature below the T_{c} of the superconductor component, applying a magnetic field to the structure, and applying electrostatic gating to the structure. Generally, at least part of the semiconductor component is in intimate contact with the superconductor component, for example the superconductor component may be epitaxially grown on the semiconductor component. Certain device structures having one or more further components between the semiconductor component and superconductor component have however been proposed.

The characterization of semiconductor-superconductor hybrid devices using local conductance measurements has been reported. In a local conductance measurement, conductance is measured between the superconductor component and one terminal of the semiconductor component.

Provided herein are methods for measuring non-local conductance of a hybrid device. Non-local conductance measurements may allow for better characterization of the properties and behaviour of semiconductor-superconductor hybrid devices. For example, the size of the topological gap induced in a device may be determined based on non-local conductance data. Further, it has been found that by electrostatically gating the semiconductor-superconductor hybrid device in a particular manner, improvements in the signal-to-noise ratio for the measurement may be achieved.

An illustrative example of a semiconductor-superconductor hybrid device will first be described with reference to FIG. 2. FIG. 2 shows a schematic cross-section of the device.

The device 200 includes a substrate, a semiconductor-superconductor hybrid structure, and a gate stack.

The substrate 210 provides a base on which the other portions of the device are fabricated. The substrate may comprise a wafer of a crystalline material. The wafer material is not particularly limited. The wafer may comprise a high-band gap semiconductor, for example a material selected from indium phosphide, gallium arsenide, and gallium antimonide.

The semiconductor-superconductor hybrid structure comprises a semiconductor component 212 and a superconductor component 216.

The semiconductor component 212 is arranged on the substrate 210. The semiconductor component typically comprises a nanowire, or network of nanowires. A network of nanowires comprises two or more connected nanowires, and may have a branched structure in plan.

The semiconductor component may comprise any suitable semiconductor material. For example, the semiconductor component 112 may comprise a Ill-V semiconductor material, such as a material of Formula 1:

InAsₓSb₁₋ₓ (Formula 1)

where x is in the range 0 to 1. In other words, the semiconductor component 112 may comprise indium antimonide (x=0), indium arsenide (x=1), or a ternary mixture comprising 50% indium on a molar basis and variable proportions of arsenic and antimony (0<x<1). Materials of Formula 1 have been found to couple particularly well to superconductor materials such as aluminium.

Another class of materials useful as the semiconductor component are II-VI semiconductor materials. Examples of II-VI semiconductor materials include lead telluride and tin telluride.

During fabrication of the device, the semiconductor component 212 may be grown epitaxially on the substrate 210, for example using selective area growth. Selective area growth uses a dielectric mask 214 arranged on the substrate 210 to control the location at which the semiconductor component 212 grows. In implementations where selective area growth is used to fabricate the device, dielectric mask 214 may remain in the finished device. Examples of materials useful as dielectric masks include silicon oxides (SiOₓ), silicon nitrides (SiNₓ), aluminium oxides (AlOₓ), and hafnium oxides (HfOₓ). Two or more dielectric layers may be present.

Other processes, such as for example the vapour-liquid-solid process, may be used to fabricate the semiconductor component.

The illustrated semiconductor component 212 has a generally trapezoidal cross-section. The cross-sectional shape is however not particularly limited and may vary depending on, for example, the process and conditions chosen for fabricating the semiconductor component.

The hybrid structure further includes superconductor component 216. The superconductor component 216 is arranged on the semiconductor component 212. The semiconductor component 212 and superconductor component 216 are configured to allow coupling of the semiconductor component 212 and superconductor component 216. Such coupling allows excitations useful for quantum computing to be induced under certain conditions.

In the illustrated example, the superconductor component 216 is in direct contact with the semiconductor component 212. For example, superconductor component 216 may be grown epitaxially on the semiconductor component 212. However, direct contact is not necessarily essential to achieve coupling. Device structures in which a further component, such as a ferromagnetic insulator, may be arranged between the semiconductor component 212 and superconductor component 216 have been proposed.

The nature of the superconductor is not particularly limited and may be selected as appropriate. The superconductor is typically an s-wave superconductor. Any of the various s-wave superconductors known the art may be used. Examples include aluminium, indium, tin, and lead, with aluminium being preferred in some contexts. In implementations where aluminium is used, the superconductor component 216 may for example have a thickness in the range 4 to 10 nm. Aluminium layers having thicknesses in this range have been reported to couple particularly well to semiconductor materials of Formula 1 (Winkler et al (Physical Review B 99, 245408 (2019)).

Device 200 may include regions where no superconductor component is present on the semiconductor component 212. In other words, superconductor component 216 does not necessarily extend along the full length of the semiconductor component 212. In particular, superconductor may be absent from terminal regions at the ends of the semiconductor component 212.

Device 200 further includes a gate stack, comprising a gate electrode 220 and a dielectric 218 arranged between the gate electrode and the other parts of the device. The illustrated example is top-gated, with the gate stack being arranged on top of the other components of the device 100.

The purpose of gate electrodes in general is to apply an electrostatic field to the semiconductor component 212 during use, in order to manipulate the number of available charge carriers in the conduction band of the semiconductor component 212.

The dielectric 218 is for preventing or reducing the flow of current from the gate electrode into the other components of the device. Any such current is referred to as leakage current. Leakage current in such a device may depend on various factors including quality, e.g. purity and thickness, of the layer of dielectric material 218.

Gating may be applied to any portion of the semiconductor component 212. A gate electrode for gating a region of the semiconductor component where the superconductor component is present may be referred to as a plunger gate. A gate electrode for gating a region of the semiconductor component where the superconductor component is not present may be referred to as a cutter gate. The gate electrode 220 illustrated in FIG. 2 is an example of a plunger gate.

The semiconductor-superconductor devices used herein have cutter gates at the terminal regions, in other words at the ends of the semiconductor component 212. The device may further include one or more plunger gates.

FIG. 2 shows just one illustrative example of a semiconductor-superconductor hybrid device, and many variations are possible.

The example device is top-gated. Other configurations of the gate stack are possible. The device may be bottom-gated. In a bottom-gated device, the gate electrode may be arranged underneath the semiconductor component, for example on an opposite surface of the substrate to the semiconductor component. In such configurations, the substrate may serve as the gate dielectric. Side-gated devices, in which the gate electrode is spaced laterally from the semiconductor component, are also possible. The inclusion of a layer of dielectric material is optional for side-gated devices, since an empty space may be left between the gate electrode and the semiconductor device and may serve as the dielectric.

The example device is horizontally orientated, in other words, the length direction of the nanowire extends parallel to the surface of the substrate. The methods provided herein are equally applicable to vertically orientated devices. Examples of vertically orientated devices are described in US 2020/0027030 A1 and US 2020/0027971 A1.

An example apparatus for measuring a non-local conductance will now be described with reference to FIG. 3. FIG. 3 is a block diagram which shows the apparatus in use, connected to a semiconductor-superconductor hybrid device. The apparatus may be removably connectable to the semiconductor-superconductor hybrid device such that when the apparatus is not in use, the semiconductor-superconductor hybrid device may be absent. Alternatively, the apparatus may be permanently connected to the semiconductor-superconductor hybrid device.

As previously described with reference to FIG. 2, the semiconductor-superconductor hybrid device 310 includes a semiconductor component 312 in the form of a nanowire and a superconductor component 314. FIG. 3 additionally illustrates that the semiconductor-superconductor hybrid device has first and second terminals provided with respective cutter gates 316, 318.

At least when the apparatus is in use, the superconductor component is connected to ground.

The first terminal of the hybrid device 310 is connected to a voltage source 320 for applying a known bias voltage to the semiconductor component 312. The first terminal may be an emitter terminal. The second terminal of the hybrid device 310 is connected to an ammeter for measuring a current through the second terminal. The second terminal may be a receiver terminal.

In the examples provided herein, the first and second terminals are also referred to as left and right terminals, respectively. It is to be appreciated that this is for convenience of description only and is not intended to limit the relative positions of the terminals in space.

The apparatus 340 includes a processing unit 342, a data storage 344, and connection circuitry 346. The processing unit is operably linked to the data storage 344 and connection circuitry 346. The data storage 220 stores a computer program which, when executed by the processing unit 342, causes the apparatus to perform a method as described herein.

The apparatus 340 may further include an optional user terminal. The user terminal may include user input equipment and a display device.

The user input equipment may comprise any one or more suitable input devices for known in the art for receiving inputs from a user. Examples of input devices include a pointing device, such as a mouse, stylus, touchscreen, trackpad and/or trackball. Other examples of input devices include a keyboard, a microphone when used with voice recognition algorithm, and/or a video camera when used with a gesture recognition algorithm.

Where reference is made herein to receiving an input from the user through the user input equipment, this may mean through any one or more user input devices making up the user input equipment.

The user input equipment may be useful for allowing a user to specify values for parameters to be investigated, such as bias voltages and gate voltages to be used. User input equipment may be omitted when the parameters are determined in some other way, for example programmatically or based on a message received over a network.

The display device may take any suitable form for outputting images, such as a light emitting diode (LED) screen, liquid crystal display (LCD), plasma screen, or cathode ray tube (CRT). The display device may comprise a touchscreen, and thus also form at least part of the user input equipment. A touchscreen may enable inputs by via being touched by the user's finger and/or using a stylus.

The inclusion of a display device is optional. A display device is useful in examples where it is desired to display a graph, or other human readable output, to a user.

The processing unit 342 may be implemented in one or more dies, IC (integrated circuit) packages and/or housings at one or more geographic sites. More than one processing unit may be present.

Each of the one or more processing units may take any suitable form known in the art, e.g. a general-purpose central processing unit (CPU), or a dedicated form of co-processor or accelerator processor such as a graphics processing unit (GPU), digital signal processor (DSP), etc. Each of the one or more processing units may comprise one or more cores. The processing units are typically classical, as opposed to quantum, processing units.

Where it is said that a computer program is executed using the processing apparatus, this may mean execution by any one or more processing units present in the apparatus.

The processing unit 342 typically further comprises working memory, such as random-access memory and/or one or more memory caches.

The data storage 344 comprises one or more memory units implemented in one or more memory media in one or more housings at one or more geographic sites.

Each of the one or more memory units may employ any suitable computer-readable storage medium known in the art, e.g. a magnetic storage medium such as a hard disk drive, magnetic tape drive etc.; or an electronic storage medium such as a solid state drive (SSD), flash memory or electrically erasable programmable read-only memory (EEPROM), etc.; or an optical storage medium such as an optical disk drive or glass or memory crystal based storage, etc. As used herein, the term “computer-readable storage medium” refers in particular to a non-transitory computer-readable storage medium.

Where it is said herein that some item of data is stored in data storage 344 or a region thereof, this may mean stored in any part of any one or more memory devices making up the data storage 344.

The processing unit 342 and data storage 344 are operably linked. The processing unit and data storage are configured such that processing unit 344 is capable of reading data from at least a portion of data storage 344, and optionally writing data to at least a portion of the data storage 344. The processing unit 342 may communicate with the data storage 344 over a local connection, e.g. a physical data bus and/or via a network such as a local area network or the Internet. In the latter case the network connections may be wired or wireless.

Apparatus 340 further includes connection circuitry 346 operably connectable to the semiconductor-superconductor hybrid device. In the illustrated example, the connection circuitry is configured to allow the apparatus 340 to control the gate voltages applied to the first and second cutter gates 316, 318; to control or receive a measurement of the bias voltage applied by the voltage source 320; and to measure the current through the second terminal using ammeter 330.

When the semiconductor-superconductor hybrid device includes one or more further gate electrodes, for example a cutter gate, the connection circuitry may be configured additionally to allow the apparatus to control the gate voltage(s) applied to the further gate electrode(s).

The voltage source 320 and ammeter 330 may be components of the apparatus 340, or may be removably connectable to the apparatus 340.

One or more components of the apparatus may be arranged on the same die as the semiconductor-superconductor hybrid device. One or more components of the apparatus may be arranged on the same circuit board as the semiconductor-superconductor hybrid device. Arranging the apparatus on the same die or the same circuit board as the hybrid device may be particularly useful in implementations where the apparatus is for controlling operating parameters of a qubit device.

Semiconductor-superconductor hybrid devices are operated in a cryogenic chamber, to allow superconductive behaviour to be induced. Components of the apparatus 340 may be arranged outside the cryogenic chamber. In particular, the voltage source and processing unit may be outside the cryogenic chamber. Cryogenic chambers have a finite refrigeration capacity, also referred to as thermal budget, and it is generally desirable to minimize the number of heat-generating components present in the chamber.

The illustrated example show the apparatus connected to a single semiconductor-superconductor hybrid device. The apparatus may alternatively be configured to be connected to a plurality of semiconductor-superconductor hybrid devices simultaneously. The plurality of semiconductor-superconductor hybrid devices may, for example, be arranged in a qubit device.

Alternative apparatuses may be used in the practice of the methods described herein. The apparatus to be used is not particularly limited, provided that the gate voltages can be controlled, a known bias voltage can be applied to the first terminal, and a current through the second terminal can be measured. The use of a processing unit and data storage to control the applied voltages and to record measurements is optional.

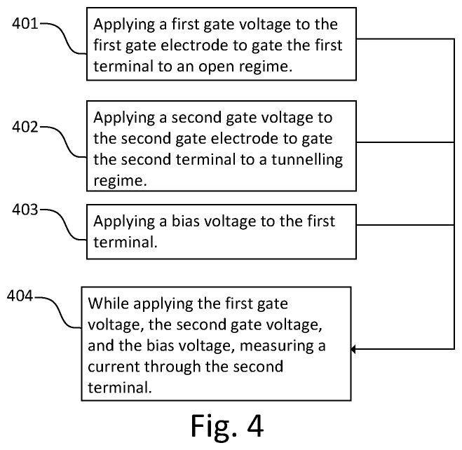

FIG. 4 is a flow chart outlining a method of measuring non-local conductance of a semiconductor-superconductor hybrid device. As described with reference to FIGS. 2 and 3, the hybrid device has first and second terminals, provided with respective cutter gates. The superconductor component is connected to ground during the measurement.

At block 401, a first gate voltage is applied to the first gate electrode 316 to gate the first terminal to an open regime. In other words, the first gate voltage is selected to increase the number of available charge carriers in the semiconductor at the first terminal. This puts the semiconductor at the first terminal into a conductive regime.

A terminal is considered to be “open”, in other words in an open regime, when it has a local conductance of greater than or equal to:

$$\frac{{e}^{2}}{h}$$

where e is the elementary charge (i.e., the absolute value of the electric charge of a single electron), and h is Planck's constant.

Local conductance is a conductance measured between the terminal and the superconductor component. The local conductance may be a high-bias local conductance. A high-bias local conductance is a local conductance measured while applying a bias voltage greater than the size of the superconducting energy gap, for example a bias voltage of at least twice the size of the superconducting gap. In particular, the local conductance may be measured at a bias voltage of twice the size of the superconducting gap. The local conductance may be measured as described in Anselmetti et al., Phys. Rev. B 100, 205412 (2019).

At the same time, at block 402, a second gate voltage is applied to the second gate electrode 318, to gate the second terminal to a tunnelling regime. Typically, the first and second gate voltages will be different.

In the tunnelling regime, an energy barrier against the flow of charge through the second terminal is generated. The second terminal is tuned to a classically non-conductive state. Any flow of current through the second terminal is by quantum tunnelling.

A terminal is in the tunnelling regime when it has a high-bias local conductance of less than, and not equal to:

$$\frac{{e}^{2}}{h}$$

where e is the elementary charge (i.e., the absolute value of the electric charge of a single electron), and h is Planck's constant.

In particular, the second terminal may be gated to a deep tunnelling regime. A terminal in the deep tunnelling regime has a high-bias local conductance of less than or equal to:

0.1e²/h

where e is the elementary charge (i.e., the absolute value of the electric charge of a single electron), and h is Planck's constant.

As with the local conductance for the first terminal, the local conductance of the second terminal is the conductance between the second terminal and the superconductor component. The local conductance may be a high-bias local conductance, measured while applying a bias voltage greater than the size of the superconducting gap, optionally at least twice the size of the superconducting gap. In particular, the high-bias local conductance may be measured at a bias voltage of twice the size of the superconducting gap.

At block 403, a bias voltage is applied to the semiconductor component via the first terminal. The magnitude of the applied voltage is known or measured. The bias voltage is applied while at the same time applying the first and second gate voltages to the respective terminals.

At block 404, while performing the operations of blocks 401, 402 and 403, a current through the second terminal is measured.

A current flows when the applied voltage exceeds a threshold corresponding to the induced energy gap in the semiconductor component of the hybrid device.

The conductance of the semiconductor component may then be calculated based on the values of the bias voltage applied to the first terminal, and the current through the second terminal. This conductance is a “non-local” conductance because it is representative of the conductance through the full length of the nanowire, from the first terminal to the second terminal. In contrast, in a “local” conductance measurement, the current between one terminal of the hybrid device and the superconductor component is measured.

By gating the first terminal to an open regime and the second terminal to a tunnelling regime, a detectable signal with a good signal-to-noise ratio may be achieved.

Other approaches to measuring non-local conductance have used symmetrical gating, with the same gate voltage being applied to both terminals. It has been found that gating both terminals to an open or intermediate regime gives a noisy signal, and that gating both terminals closed does not give a measurable current through the nanowire.

Various modifications may be made to the method.

The bias voltage may be varied and the current through the second terminal may be measured as a function of the bias voltage. For example, a scan of the bias voltage may be performed. The range to be scanned may be selected as appropriate depending on the characteristics of the semiconductor-superconductor hybrid device. The scan may, for example, cover bias voltages in the range −500 to +500 μV, optionally −300 to +300 μV, optionally 0 to 500 μV, optionally 0 to 300 μV.

Performing such a scan may be useful for determining the minimum bias voltage which will cause a current to flow from one of the terminals of the semiconductor component to the other of the terminals of the semiconductor component. This minimum bias voltage may provide an indication of the size of an induced energy gap in the semiconductor-superconductor hybrid device.

A measure of the size of the topological gap may be obtained from the conductance data by determining the bias voltage at which the measured non-local conductance value exceeds a predetermined threshold. The predetermined threshold is set to be greater than the noise floor of the apparatus. The noise floor is the sum of all noise sources and unwanted signals within the apparatus, with all signals other than those representative of the non-local conductance being considered “unwanted”.

Alternatively, the size of the topological gap may be obtained from the conductance data by calculating a first derivative of the conductance with respect to the applied bias voltage and finding the lowest applied bias voltage where the first derivative has a non-zero slope.

According to a still further possibility, the size of the topological gap may be determined by fitting a curve to the data and estimating the gap size to be associated with the peak position at lowest bias voltage.

Other techniques for determining the size of an induced gap based on the non-local conductance measurement may be used.

In addition, or as an alternative to varying the bias voltage, one or both of the first and second gate voltages may be adjusted. In particular, the gate voltages may be adjusted while applying a fixed bias voltage.

Adjusting the gate voltages may allow the signal-to-noise ratio for optimization of the signal-to-noise ratio for the measurement.

Adjusting the gate voltages may also modify the behaviour of the semiconductor-superconductor hybrid device. For example, varying one or both of the gate voltages may change the magnitude of the energy gap induced in the hybrid device. The gate voltages may be adjusted to maximize the size of the induced energy gap, e.g. the topological gap. Alternatively, the gate voltages may be adjusted to obtain an induced energy gap having a size within a predetermined range. The predetermined range may be a range from 20% to 80% of the superconductor gap of the superconductor component.

In examples where the hybrid device includes one or more further gate electrodes, gate voltages may be applied to the further electrodes during the measurement. The gate voltage(s) applied to the further electrode(s) may be varied, for example to maximize the size of the induced energy gap, or to obtain an induced energy gap within the predetermined range.

Adjustments to values of operating parameters for the semiconductor-superconductor hybrid device may be performed based on an optimization algorithm. The nature of the optimization algorithm is not particularly limited, and may be selected as appropriate from the various optimization algorithms known in the field of machine learning. The optimization may comprise iterative adjustments. For example, a gradient descent or ascent algorithm such as stochastic gradient descent may be used.

The optimization algorithm may vary the values of one or more parameters selected from the bias voltage, the first gate voltage, and the second gate voltage. When one or more further gate electrodes are present, the one or more parameters may comprise gate voltage(s) for the further gate electrode(s).

Initial values for the one or more parameters may be based on an input received from a user, for example via the user input equipment of apparatus 340. Alternatively, initial values may be determined programmatically, for example based on stored values from previous optimizations or on a model or simulation of the semiconductor-superconductor hybrid device.

The optimization algorithm may be configured to determine optimized values for the one or more parameters, which values correspond to a target outcome. The target outcome may be a maximum signal-to-noise ratio for the measurement of non-local conductance. The target outcome may be a maximum magnitude and/or visibility of an induced energy gap such as a topological gap. The target outcome may be to obtain an induced energy gap having a size within a predetermined range, e.g. 20% to 80% of the size of the superconducting gap. The magnitude of the induced energy gap may be determined as described above.

The output of an optimization algorithm comprises optimized values for the one or more parameters. The optimized values may be written to a data storage, such as data storage 344 of apparatus 340; output in a human-readable format e.g. displayed on a display device of apparatus 340; transmitted over a network to another entity; and/or used by e.g. apparatus 340 to control operation of the device.

In implementations where the optimized values are written to a data storage, if a repeat optimization is performed then the initial values for the repeat may be determined based on the stored optimized values. Repeating the optimization for the same device periodically, e.g. daily or weekly, may be useful because certain hybrid structures can degrade over time.

One or more parameters selected from the bias voltage, the first gate voltage, and the second gate voltage may be selected in accordance with a machine learning algorithm, for example an artificial neural network.

Training data for the machine learning algorithm may comprise optimized values for the bias voltage, first gate voltage, and second gate voltage in respect of a plurality of hybrid devices. The training data may comprise empirical data obtained by experiment, e.g. results of manual optimizations and/or stored optimized values generated using an optimization algorithm as described above. Additionally or alternatively, the training data may comprise optimized values generated by simulation.

The machine learning algorithm may be configured to determine optimized values for the one or more parameters, which values correspond to a target outcome. The target outcome may be a maximum signal-to-noise ratio for the measurement of non-local conductance. The target outcome may be a maximum magnitude and/or visibility of an induced energy gap. The target outcome may be to obtain an induced energy gap having a magnitude within a predetermined range.

Although the example method has been described with reference to a single semiconductor-superconductor hybrid device, the method may be performed on a plurality of semiconductor-superconductor hybrid devices. The plurality of semiconductor-superconductor hybrid devices may, for example, be arranged as a qubit device. Non-local conductances of individual ones of the plurality of hybrid devices may be measured consecutively or concurrently. This may be useful for selecting operating parameters for the qubit device, for example identifying bias voltage(s) and gate voltage(s) at which individual hybrid devices have induced gaps with magnitudes in a desired range.

It will be appreciated that the above embodiments have been described by way of example only.

More generally, according to one aspect disclosed herein, there is provided a method for measuring a non-local conductance of a semiconductor component of a semiconductor-superconductor hybrid device. The semiconductor-superconductor hybrid device comprises: the semiconductor component, the semiconductor component having a first terminal and a second terminal; a first gate electrode for electrostatically gating the first terminal; a second gate electrode for electrostatically gating the second terminal; and a superconductor component configured to be capable of energy level hybridisation with the semiconductor component; the method comprising: applying a first gate voltage to the first gate electrode to gate the first terminal to an open regime; applying a second gate voltage to the second gate electrode to gate the second terminal to a tunnelling regime; applying a bias voltage to the first terminal; and while applying the first gate voltage, the second gate voltage, and the bias voltage, measuring a current through the second terminal; wherein, during the measurement, the superconductor component is grounded. It has been found that, by tuning the first terminal of the semiconductor component to an open regime, tuning the second terminal to a tunnelling regime, applying a bias voltage to the first terminal, and measuring current through the second terminal, a measurement of non-local conductance through the semiconductor component having a good signal-to-noise ratio may be obtained. The non-local conductance may be subsequently used to determine characteristics of the hybrid device.

The first and second gate electrodes may each be cutter gates. In other words, the first and second terminals may be regions of the semiconductor component which do not have superconductor material thereover.

The semiconductor component may comprise a nanowire of semiconductor material having first and second ends. The superconductor component may be arranged over a portion of the nanowire. The superconductor component may be spaced from the first and second ends of the nanowire to define the first and second terminals.

The tunnelling regime may be a deep tunnelling regime.

The method may further comprise varying one or more of the bias voltage, first gate voltage and second gate voltage. Varying the applied voltages may change the behaviour of the semiconductor-superconductor hybrid devices.

The methods provided herein may be controlled by a computer. For example, the semiconductor-superconductor hybrid device may be operably connected to an apparatus comprising a processing unit and a data storage. The processing unit may control one or more of the bias voltage, the first gate voltage, and the second gate voltage; and receive the measurement of the current.

The processing unit may be a classical processing unit.

The method may further comprise determining, based on the measurement, a magnitude of an energy gap induced in the semiconductor-superconductor hybrid device. For example, the determination may comprise identifying a minimum bias voltage which corresponds to a non-local conductance greater than a noise floor of the measurement. The determination may comprise fitting a model to the measurement.

The determination may be performed by the processing unit of the apparatus.

The method may comprise adjusting one or more of the bias voltage, the first gate voltage, and the second gate voltage. The adjustment may be controlled by the processing unit. For example, the processing unit may execute an optimization algorithm as described hereinabove. The processing unit may use an optimisation algorithm to determine optimized values for one or more of the bias voltage, the first gate voltage, and the second gate voltage corresponding to a target outcome.

Adjustments and/or optimizations may alternatively be manually controlled.

The target outcome may be to increase the visibility of the energy gap, for example to obtain a non-local conductance which is greater than a predetermined threshold. The predetermined threshold may be a noise floor for the apparatus used to perform the measurement.

The target outcome may comprise a signal-to-noise ratio for the measurement which is greater than or equal to a predetermined threshold.

The target outcome may comprise a magnitude of an energy gap induced in the semiconductor-superconductor hybrid device which is within a predetermined range.

The predetermined range may be a range from 20% to 80% of the superconductor gap of the superconductor component. It is believed that induced gaps having magnitudes outside of this range may be less useful for quantum computing.

Alternatively, the predetermined range may be a range of greater than or equal to a predetermined threshold value.

The processing unit may select a static value for the bias voltage, and to vary the first and/or second gate voltages.

The semiconductor-superconductor hybrid device may be present in a device comprising a plurality of semiconductor-superconductor hybrid devices. The device comprising the plurality of semiconductor-superconductor hybrid devices may be, for example, a qubit device.

Non-local conductance measurements may be performed on individual ones of the semiconductor-superconductor hybrid devices concurrently or consecutively.

Induced gaps, e.g. topological gaps, for individual ones of the plurality of semiconductor-superconductor hybrid devices may be determined.

The bias voltage, first gate voltage, and second gate voltage for individual ones of the semiconductor-superconductor hybrid devices may be independently selected. In other words, the voltages applied to individual devices may be different. The voltages may be adjusted as described above, for example to induce an energy gap in the semiconductor-superconductor hybrid device which is within a predetermined range.

Another aspect provides an apparatus for measuring a non-local conductance of a semiconductor component of a semiconductor-superconductor hybrid device, the semiconductor-superconductor hybrid device having a semiconductor component and a superconductor component, the superconductor component being configured to be capable of energy level hybridisation with the semiconductor component, which apparatus comprises: a processing unit; a data storage; and connection circuitry operably connectable to the semiconductor-superconductor hybrid device; wherein the data storage stores code which, when executed by the processing unit, causes the apparatus to perform operations comprising: applying a first gate voltage to a first gate electrode to gate a first terminal of the semiconductor component to an open regime; applying a second gate voltage to a second gate electrode to gate a second terminal of the semiconductor component to a tunnelling regime; applying a bias voltage to the first terminal; and while applying the first gate voltage, the second gate voltage, and the bias voltage, measuring a current through the second terminal. The apparatus is useful for performing the method provided herein.

The apparatus may be configured to implement the operations described above with respect to the method aspect.

The tunnelling regime may be a deep tunnelling regime.

The apparatus may include the semiconductor-superconductor hybrid device. In such implementations, the connection circuitry is connected to the semiconductor-superconductor hybrid device.

The operations may further comprise connecting the superconductor component to ground. Alternatively, the semiconductor-superconductor device may be configured such that the superconductor component is connected to ground.

The operations may further comprise determining, based on the measured current, the magnitude of an energy gap induced in the semiconductor-superconductor hybrid device. The determination may comprise fitting a model to the measurement. The determination may comprise identifying a minimum bias voltage which corresponds to a non-local conductance greater than a noise floor of the measurement.

The operations further comprise adjusting one or more of the first gate voltage, the second gate voltage, and the bias voltage. For example, the operations may comprise selecting and applying a static bias voltage, and adjusting one or both of the first and second gate voltages.

The adjustment may comprise using an optimisation algorithm to determine optimized values for one or more of the bias voltage, the first gate voltage, and the second gate voltage to obtain a target outcome. The target outcome comprises a signal-to-noise ratio for the measurement which is greater than or equal to a predetermined threshold. The target outcome may comprise a magnitude of an energy gap induced in the semiconductor-superconductor hybrid device which is within a predetermined range.

The apparatus may be configured to perform measurements on, and/or control operation of, a plurality of semiconductor-superconductor hybrid devices. For example, the connection circuitry may be operably connectable to a plurality of semiconductor-superconductor hybrid devices. The code may be configured to cause the apparatus to perform the operations on the plurality of semiconductor-superconductor hybrid devices.

The operations may comprise applying independently selected first gate voltages, second gate voltages, and bias voltages to individual ones of the semiconductor-superconductor hybrid devices.

The apparatus may be configured to perform the operations on at least two of the semiconductor-superconductor hybrid devices simultaneously. Alternatively, the operations may be performed on individual ones of the semiconductor-superconductor hybrid devices consecutively.

The plurality of semiconductor-superconductor hybrid devices may be arranged in a qubit device.

A still further aspect provides a computer-readable medium storing code which, when executed by a processing unit of an apparatus having connection circuitry operably connectable to the semiconductor-superconductor hybrid device, causes the apparatus to perform a method as defined herein.

The operations may comprise applying a first gate voltage to a first gate electrode to gate a first terminal of the semiconductor component to an open regime; applying a second gate voltage to a second gate electrode to gate a second terminal of the semiconductor component to a tunnelling regime; applying a bias voltage to the first terminal; and while applying the first gate voltage, the second gate voltage, and the bias voltage, measuring a current through the second terminal.

The computer-readable medium is typically a non-transitory computer readable medium. The computer-readable medium may be a non-volatile memory, such as a hard drive, solid state drive, or ROM chip.

### Example 1

A device as shown in FIG. 2B was fabricated on a hybrid InAs/Al nanowire grown by Selective Area Growth, similar to the process described in Vaitiekenas et al., Phys. Rev. Lett. 121, 147701. The non-local conductance of the device as a function of applied bias voltage on the left terminal was measured using a method as described with reference to FIG. 4. The left bias voltage was varied from −500 to 500 μV.

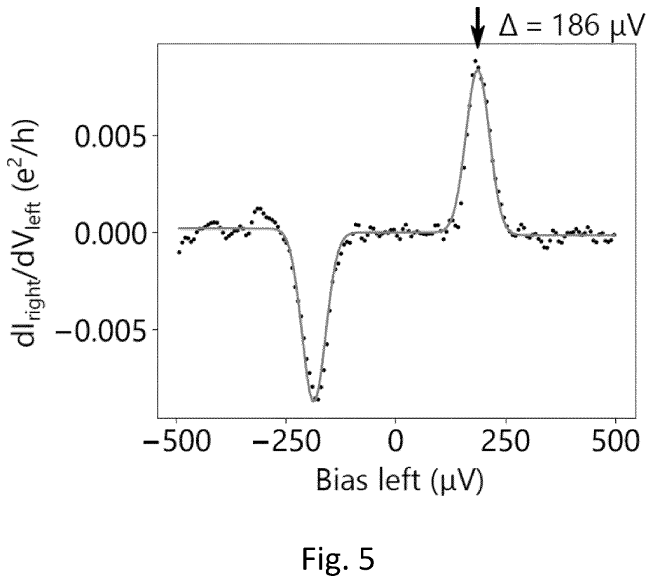

A plot showing non-local conductance, i.e. the derivative of current through the second terminal (dI_{right}) with respect to the bias voltage applied at the first terminal (dV_{left}), as a function of applied bias voltage is shown in FIG. 5.

The magnitude of the non-local conductance is consistent with zero in a bias voltage range around zero bias. At higher applied bias voltages there is an onset of finite non-local conductance, corresponding the edge of the induced gap. To quantify this gap, a peak fit is performed, and the peak center yields the value of the induced gap, in this case Δ=186 μV.

While the local conductance (e.g. the derivative of current through the first terminal with respect to voltage applied at the first terminal dI_left/dV_left) is typically positive, the non-local conductance (e.g. dI_left/dV_right) can be negative as well as positive depending on the particulars of the electron transport mechanism. The non-local conductance is approximately antisymmetric with respect to bias voltage, as usually observed and expected from theory in certain scenarios.

Other variants or use cases of the disclosed techniques may become apparent to the person skilled in the art once given the disclosure herein. The scope of the disclosure is not limited by the described embodiments but only by the accompanying claims.

1-15. (canceled)

16. A method for measuring a non-local conductance of a semiconductor component of a semiconductor-superconductor hybrid device,
wherein the semiconductor-superconductor hybrid device comprises:
the semiconductor component, the semiconductor component having a first terminal and a second terminal;
a first gate electrode for electrostatically gating the first terminal;
a second gate electrode for electrostatically gating the second terminal; and
a superconductor component configured to be capable of energy level hybridisation with the semiconductor component;
the method comprising:
applying a first gate voltage to the first gate electrode to gate the first terminal to an open regime;
applying a second gate voltage to the second gate electrode to gate the second terminal to a tunnelling regime;
applying a bias voltage to the first terminal; and
while applying the first gate voltage, the second gate voltage, and the bias voltage, measuring a current through the second terminal, wherein, during the measurement, the superconductor component is grounded.

17. The method according to claim 16, wherein the tunnelling regime is a deep tunnelling regime.

18. The method according to claim 16, further comprising varying one or more of the bias voltage, the first gate voltage and/or the second gate voltage.

19. The method according to claim 16, wherein the semiconductor-superconductor hybrid device is operably connected to an apparatus comprising a processing unit and a data storage,
wherein the processing unit:
controls one or more of the bias voltage, the first gate voltage, and the second gate voltage; and
receives the measurement of the current.

20. The method according to claim 19, wherein the processing unit to determines, based on the measurement, a magnitude of an energy gap induced in the semiconductor-superconductor hybrid device.

21. The method according to claim 19, wherein the determination comprises identifying a minimum bias voltage which corresponds to a non-local conductance greater than a noise floor of the measurement.

22. The method according to claim 19, wherein the processing unit uses an optimisation algorithm to determine optimized values for one or more of the bias voltage, the first gate voltage, and the second gate voltage to obtain a target outcome.

23. The method according to claim 22, wherein the target outcome comprises a magnitude of an energy gap induced in the semiconductor-superconductor hybrid device which magnitude is within a predetermined range.

24. The method according to claim 16, wherein the semiconductor-superconductor hybrid device is present in a qubit device comprising a plurality of semiconductor-superconductor hybrid devices.

25. An apparatus for measuring a non-local conductance of a semiconductor component of a semiconductor-superconductor hybrid device, the semiconductor-superconductor hybrid device having a semiconductor component and a superconductor component, the superconductor component being configured to be capable of energy level hybridisation with the semiconductor component, which apparatus comprises:
a processing unit;
a data storage; and
connection circuitry operably connectable to the semiconductor-superconductor hybrid device;
wherein the data storage stores code which, when executed by the processing unit, causes the apparatus to perform operations comprising:
applying a first gate voltage to a first gate electrode to gate a first terminal of the semiconductor component to an open regime;
applying a second gate voltage to a second gate electrode to gate a second terminal of the semiconductor component to a tunnelling regime;
applying a bias voltage to the first terminal; and
while applying the first gate voltage, the second gate voltage, and the bias voltage, measuring a current through the second terminal.

26. The apparatus according to claim 25, wherein the operations further comprise connecting the superconductor component to ground.

27. The apparatus according to claim 25, wherein the operations further comprise determining, based on the measured current, a magnitude of an energy gap induced in the semiconductor-superconductor hybrid device.

28. The apparatus according to claim 27, wherein the determination comprises identifying a minimum bias voltage which corresponds to a non-local conductance greater than a noise floor of the measurement.

29. The apparatus according to claim 25, wherein the operations further comprise adjusting one or more of the first gate voltage, the second gate voltage, and the bias voltage.

30. The apparatus according to claim 29, wherein the operations comprise selecting and applying a static bias voltage, and adjusting one or both of the first and second gate voltages.

31. The apparatus according to claim 29, wherein the adjustment comprises using an optimisation algorithm to determine optimized values for one or more of the bias voltage, the first gate voltage, and the second gate voltage to obtain a target outcome.

32. The apparatus according to claim 31, wherein the target outcome comprises a magnitude of an energy gap induced in the semiconductor-superconductor hybrid device which is within a predetermined range.

33. The apparatus according to claim 25, wherein:
the connection circuitry is operably connectable to a plurality of semiconductor-superconductor hybrid devices; and
the code is configured to cause the apparatus to perform the operations on the plurality of semiconductor-superconductor hybrid devices.

34. The apparatus according to claim 33, wherein the plurality of semiconductor-superconductor hybrid devices are arranged in a qubit device.

35. A non-transitory computer-readable medium storing code which, when executed by a processing unit of an apparatus having connection circuitry operably connectable to a semiconductor-superconductor hybrid device, causes the apparatus to perform operations comprising:
applying a first gate voltage to a first gate electrode to gate a first terminal of a semiconductor component to an open regime;
applying a second gate voltage to a second gate electrode to gate a second terminal of the semiconductor component to a tunnelling regime;
applying a bias voltage to the first terminal; and
while applying the first gate voltage, the second gate voltage, and the bias voltage, measuring a current through the second terminal.
